(19) United States
(12) Patent Application Publication
(10) Pub. No.: US 2015/0091114 A1
(43) Pub. Date: Apr. 2, 2015

(54) Elemental Stacked Image Sensor

(71) Applicant: Forza Silicon Corporation, Pasadena, CA (US)

(72) Inventors: Barmak Mansoorian, La Canada Flintridge, CA (US); Daniel Van Blerkom, Altadena, CA (US)

(21) Appl. No.: 14/504,270

(22) Filed: Oct. 1, 2014

Related U.S. Application Data
(60) Provisional application No. 61/885,342, filed on Oct. 1, 2013.
(60) Provisional application No. 61/926,607, filed on Jan. 13, 2014.

(51) Int. Cl. H01L 27/146; H01L 31/0304; H01L 31/028; H01L 31/08; H01L 27/144

(52) U.S. Cl. CPC H01L 27/14636; H01L 31/08; H01L 27/1446; H01L 31/028; H01L 31/0304
USPC 257/431

(57) ABSTRACT

Provided herein is a novel stacked pixel design for image sensor applications. The stacked pixel designs may comprise a first and second wafer, wherein the first wafer is an elemental wafer comprising a photodiode and minimal additional components, such that material selection and processing steps of the first wafer may be optimized for the creation of a high quality photodiode. The second wafer comprises components necessary for the readout and reset of the photodiode on the first wafer.

### CROSS-REFERENCE TO RELATED APPLICATIONS

This application claims the benefit of priority to U.S. Provisional Application Ser. No. 61/885,342, entitled “Elemental Stacked Image Sensor,” filed Oct. 1, 2013, and to U.S. Provisional Application Ser. No. 61/926,607, entitled “Elemental Stacked Image Sensor,” filed Jan. 13, 2014, the contents of both of which are hereby incorporated by reference.

### STATEMENT REGARDING FEDERALLY SPONSORED RESEARCH OR DEVELOPMENT

Not applicable.

### REFERENCE TO SEQUENCE LISTING, A TABLE, OR A COMPUTER PROGRAM LISTING COMPACT DISK APPENDIX

Not Applicable

### BACKGROUND OF THE INVENTION

As CMOS image sensor technology has progressed, pixel size has become increasingly smaller. Meanwhile, four- and five-transistor designs have become common. To accommodate the additional components required for low-noise, high resolution imaging, active pixels have a smaller photosensitive area. Additionally, the close proximity of the components to each other in the packed space requires complicated architecture and complex fabrication schemes, in order to avoid leaks, electrical crosstalk, parasitic capacitance, and other complications that result from closely spacing components and wires on a wafer.

Dark current is an especially problematic issue in crowded pixel architectures. The dark current and dark current distribution of CMOS image sensors sets an upper limit to the performance of these devices for night vision, scientific, and digital still camera applications. The dark current is a strong function of the sensor's temperature. Cooling can be used to reduce the dark current in some scientific applications. However, the power consumption and cost required for cooling techniques, limit its usefulness for hand held night vision and consumer applications.

Night vision applications typically require a total noise budget of <1 e- and have pixel sizes >5 um. These requirements imply a dark current rate of <16 e-/sec at 60° C. for a 60 frame/sec device (to obtain <1e-dark signal noise for each 16 msec frame). This number is also consistent with requirements for SLR applications where a dark current of <0.1 e-/sec is required at 20° C. (in this case, to support long exposures).

From a physics based model the total dark current (I_{dark}) can be reduced by minimizing its four (4) constituent components: Surface dark current generated by interface traps at Si—SiO₂ interface (I_{FrontSurf}) at the front surface; (2) Generation current in the depletion layer (I_{dep}); (3) The diffusion current from the neutral bulk (I_{bulk}); and (4) Surface dark current generated by interface traps at the back interface (I_{BackSurf}).

Dark current can be calculated as depicted in Equation 1 and Equation 2:

$$\begin{matrix}{I}_{dark} = {I}_{FrontSurf} + {I}_{dep} + {I}_{bulk} + {I}_{BackSurf} & Equation 1 \\ {I}_{dark} = {qn}_{i} ( {S}_{gFront} + \frac{W}{{τ}_{g}} + \frac{{n}_{i} {D}_{n}}{{N}_{A} {L}_{n}} + {S}_{gBack} ) & Equation 2\end{matrix}$$

Where q, nᵢ, S_{g}, W, τ_{g}, Dₙ, N_{A}, and Lₙ denote the: elementary electric charge, intrinsic carrier concentration, surface generation velocity, width of the depletion layer, generation lifetime, electron diffusion constant, acceptor concentration, and minority carrier diffusion length, respectively.

From an intuitive based model, the most important requirements to achieve a low dark current is to: (1) Start with “perfect” silicon wafers with very low impurity levels; and (2) Minimize the process induced defects.

At the moment, CMOS image sensors integrate a complex set of devices in the same wafer. In a typical process, these include: (1) Pinned photodiode structure and associated transfer gate; (2) Three (3) other pixel transistor types (reset, source follower, and select transistor) all potentially with their own processing requirements; (3) High/low voltage PMOS transistors for signal processing and logic; (4) High/low voltage NMOS transistors for signal processing and logic; (5) Isolation structures (STI, diffusion, LOCOS, etc.) to keep the transistor types from crosstalk and latchup; and (6) Various implants for ESD and other ancillary chip functions.

The complexity of the process: (1) Reduces choices for the starting material and substrate diffusions (i.e. the starting substrates will most likely not be “perfect” with low impurity levels; and (2) Creates many process induced defects by repeated implant steps, Specifically, isolation technologies such as shallow trench isolation (STI) cause significant local damage to the silicon and cause high electric field “hot spots”. These have been specially shown to be major contributors to dark current and dark current distribution in image sensors.

Stacked image sensor designs are known in the art. For example, the Sony Exemor™ image sensors comprise a stacked pixel design wherein pixel components are distributed between a photodiode wafer and a signal processing wafer. However, a substantial number of components appear to be present on the photodiode wafer. Additional stacked pixel designs are described in U.S. Pat. No. 8,773,562, entitled “Vertically Stacked Image Sensor,” by Fan. These sensors rely on a complicated vertical transfer gate design.

Accordingly, there is a need in the art for new active pixel sensor designs which avoid the materials and process constraints which limit the performance of image sensor, and which provide greater simplicity in design and fabrication than the prior art stacked pixels

### SUMMARY OF THE INVENTION

Provided herein is a new design concept which meets the aforementioned needs and provides the art with simpler, high-quality photosensor designs, while simplifying manufacturing protocols. The invention encompasses the use of a stacked pixel, comprising a top layer with a photodiode and transfer gate, and a bottom layer comprising circuitry for storing signals, reading signals out, and resetting components. This advantageously allows the use of high quality materials in the photodiode layer, optimized for low-noise harvesting of light induced charge, while using a wafer optimized for device fabrication and performance on the bottom wafer. The simple process steps allow the use of a wide range of starting wafer material and a wide latitude for selecting the process thermal budget. These allow the optimization of the photodiode an transfer gate functions and can create features such as transistor isolation without added layers.

### BRIEF DESCRIPTION OF THE DRAWING

FIG. 1 depicts a cross sectional diagram of the stacked pixel design of the invention. Components are not to scale.

### DETAILED DESCRIPTION OF THE INVENTION

Novel Devices of the Invention.

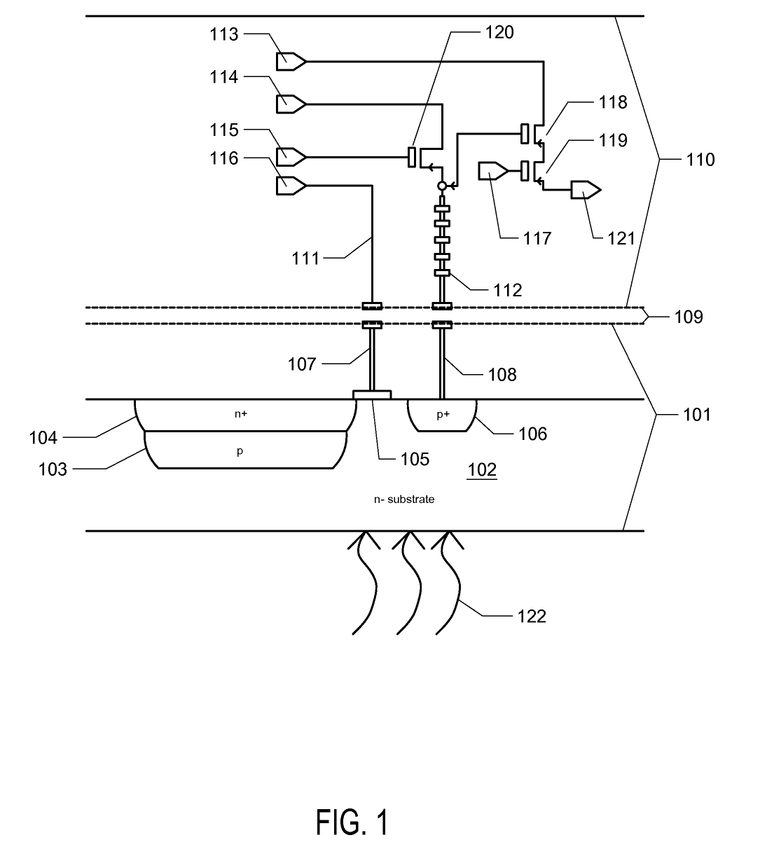

In one aspect, the invention encompasses novel pixel devices utilizing stacked, bonded wafers to create functional pixels, i.e. each pixel being a discreet photosensor element capable of converting incident light to charge, converting charge to a readout signal, and outputting such signal to a memory or signal processing component. In one embodiment, the stacked pixel of the invention comprise a photodiode, a transfer gate, and two interconnects, which are fabricated on a first wafer, while the remaining components required for pixel function are fabricated on a second wafer, as illustrated in FIG. 1. The two wafers are then aligned and bonded to create a functional photosensor element.

Reference will be made to pixel components residing on a first and a second wafer, and the description herein will be directed to the configuration of the components making up each individual pixel. It will be understood that components of multiple pixels will be present on each wafer, the wafers being aligned and bonded together to create image sensors, comprising arrays of stacked pixels.

The key feature of the invention is the fabrication of pixel components on a first wafer having minimal structures, for example, in some embodiments, the first wafer comprising only a photodiode and a transfer gate. This simplified wafer affords great advantages in performance and ease of processing, as discussed below. The transfer gate of each pixel comprises a metal gate terminal and underlying dielectric, which bridges the photodiode on its source side and a doped region on its drain side. To clarify, references made herein to a “transfer gate” will be understood to include this doped drain region as well as the gate terminal and dielectric. It will be understood by one of skill in the art that such doped drain region will also function as the floating diffusion node, or as a part of the floating diffusion node, in those embodiment where the floating diffusion node is distributed among multiple components.

In one implementation, the stacked pixel of the invention comprises a first wafer comprising a photodiode, a transfer gate, and two interconnects. One interconnect provides a conduit for voltage signals to operate the transfer gate and one interconnect provides a conduit for charge carriers to travel from the first wafer to the second wafer when the transfer gate is opened. In some implementations, additional components necessary for pixel function (e.g. readout and reset) may be present on the first wafer. In some embodiments, a third interconnect is present, for example in connection with the photodiode or pinned region of the photodiode, such third line acting as a substrate bias such as a ground or power supply.

In another implementation, the first wafer of the stacked pixel of the invention comprises what will be termed an “elemental wafer,” or “elemental first wafer” comprising a photodiode, a transfer gate, and two interconnects and not comprising any other components necessary for pixel readout and reset. Pixels comprising an elemental wafer will not contain a source follower, row select transistor, reset transistor, or sample and hold capacitors for signal storage on such elemental first wafer. However, such elemental first wafer may comprise layers such as color filters, antireflective coatings, microlenses, and other optical components not implicated in photodiode readout or reset. Such first elemental wafer may further comprise a passivation layer or layers.

This design limits the dark signal and dark signal distribution by using an elemental process to create the image sensor. For example, the invention may be implemented as a design which limits the type of devices on the image sensor wafer to only two types: (1) A back-side illuminated “pinned” photodiode-N or P type; and (2) A transfer gate-N or P type depending on typed of pinned photodiode, and substrate. This first wafer (containing the photodiode) is bonded to a second wafer (containing the signal processing means of the invention), which is made using a standard CMOS process. In one embodiment, the remaining devices, including those required to complete the pixel, will reside on this second wafer, e.g., reset transistor, source-follower, and select transistor for a non-shared 4T pixel. Depending on how the floating diffusion node is configured, it may be located on portions of both wafers, and may also comprise the interconnect between the wafers. For example, the floating diffusion may be configured as the following three elements: (1) the doped region drain side region of the transfer gate on the first wafer (2) the interconnect between the two wafers, connecting elements (1) and (3); and (3) a metal stack on the second wafer in connection with the source follower amplifier.

In another exemplary embodiment, each stacked pixel will be made up of a first wafer comprising: (1) A pinned photodector, a transfer gate; and (2) two DBI or high density wafer to wafer interconnects; and a second wafer comprising the remaining active or passive devices necessary for reading charge accumulated by the photodiode and resetting the components of the pixel. These devices may include: the remainder of the floating diffusion structure; a reset transistor, source-follower, and select transistor for a non-shared 4T pixel. The second wafer may further comprise additional devices required for more complex pixel types such as pinned charge transimpedance (PCTIA) pixels, global shutter pixels, or high dynamic range pixels. Fewer devices may be needed in the case of shared pixel architectures, wherein adjacent pixels share one or more components for readout or reset operations.

An exemplary embodiment of the invention is depicted in FIG. 1. FIG. 1 depicts a pixel comprising a first wafer (101) comprising the photodiode. The photodiode comprises a p-doped region (103), n+ doped pinning layer (104) in an n-substrate (102). A transfer gate (105) adjacent to the photodiode controls the flow of charges to a p+ doped region (106). Interconnects on the first wafer (107 and 108), such as DBI interconnects, as known in the art, connect to corresponding interconnects (111 and 112) on the second wafer. The second wafer (110) comprises voltage sources and/or connections such as a ground (113), a reset voltage source (114), a reset gate signal line (115) which controls the reset gate (120) and a transfer gate signal line (116), which, via interconnects on the second (111) and first wafers (107), controls the transfer gate (105). Components further may include a source follower amplifier (118), a row select signal line (117) which controls a row select gate (119). A signal output line (121) outputs to a column bus (not shown). The optional interlayer between the wafers (109) may or may not be present, and if not present, the two wafers are directly in contact. The second wafer interconnect (112) which connects to the floating diffusion node on the first wafer may optionally comprise a metal stack, for example, a six layer metal stack, for example having less than 0.1 fF parasitic capacitance at 90 nm. This structure may act in part as an element of the floating diffusion node. Light (122) is incident upon the pixel.

It will be understood that the exemplary circuit depicted in FIG. 1 may be configured in various ways, and may further comprise components such as sample and hold capacitors and other structures for operations such as correlated double sampling, global shutter operation, and other functions.

The wafers are bonded and electrically connected using any process known in the art for wafer bonding, including direct wafer bonding, thermocompressive bonding, adhesive bonding, etc. Exemplary bonding techniques include plasma-activated silicon oxide bonding and polymer adhesive bonding. An exemplary bonding technique is a high-density connection process such as Direct Bonding Interface technology. Alignment of wafers by mechanical or optical means, as known in the art, may be used. Interconnects may be of any type known in the art, for example through-silicon vias. For example, in the configuration illustrated in FIG. 1, two interconnects are utilized; an interconnect which allows operation of the transfer gate and an interconnect which allows charge accumulated on the floating diffusion node to move to the source-follower amplifier. It will be understood by one of skill in the art that the number and type of interconnects will depend on the distribution of elements on the two wafers.

The wafer stack of the invention may comprise an intermediate layer or layers, for example a layer comprising an adhesive, a layer comprising an insulating material, dielectric material, etc.

In some embodiments, it will be preferred that the connections between the two halves of the pixel (between wafer1 and wafer2) be as short and vertical as possible, in order to (1) reduce the possibility of inverting the substrate away from the associated device (as no passivation is present), and (2) to reduce the parasitic capacitance at the floating diffusion node.

The design concept described herein imparts many advantages. First, the design alleviates some of the crowding that inevitably occurs in a standard pixel, as components may now reside on two separate levels. This alleviates some of the design constraints dictated by interference among components and wiring and allows more design freedom.

Additionally, the use of two (or more) wafers allows for optimized substrate material selection and processing techniques for the components of each wafer, avoiding compromises in sensor performance and alleviating the need for complicated fabrication schemes that result when all components of a pixel are required to use a single fabrication process regime. For example, a large, high-quality photodiode made using substrates, tools, processing methods, and rules which are optimal for the creation of high quality photodiodes may be employed. For example, the first wafer photodiode and transfer gate may be made using 180 nm processing. The bottom wafer, housing the remainder of the sensor components, may for example be fabricated using 65 nm processing.

In one embodiment, the photodiode wafer may comprise a low-doped silicon wafer, which allows a very large diffusion width for the photodiode with relatively low dark current. Such a configuration is especially applicable in making near-infrared detectors.

The designs of the invention allow more facile and effective implementations of various improvements to the photodiode. For example, a deeper potential well layer may be made. For example, a second potential well layer may be implanted below the upper potential-well layer in the photodiode. A deeper and/or multi-layer potential well layer allows performance enhancements such as vertical anti-blooming and/or global shutter capabilities, as known in the art.

The selection of photodiode type will depend on the specific applications for which the sensor is designed. The optimal substrate materials and processing methods will depend on the type of photodiode selected, as known in the art. Any photodiode type known in the art may be employed in the practice of the invention. For example, as depicted in FIG. 1, a P-well/n-substrate architecture is depicted. The photodiodes of the invention may also comprise N-well/p-substrate designs, as known in the art. P—N, P—I—N, avalanche photodiodes, reverse avalanche photodiodes may also be used. The use of pinned photodiodes is preferred. Non-silicon photodiode materials, for example gallium arsenide (GaAs), Indium gallium arsenide, or germanium may also be used to the extent that they are compatible with wafer level processing or integration with silicon wafers and to the extent that they may be efficiently bonded with silicon wafers.

While the invention is described with reference to a two-wafer stack, it will be understood by one of skill in the art that three or more bonded wafers may be used, for example a top wafer comprising the photodiode and transfer gate, an intermediate wafer comprising a subset of the sensor components, and a bottom wafer comprising the remaining sensor components, with appropriate interconnects between the wafers to provide a functional pixel sensor.

In one embodiment, the pixel of the invention comprises a backside-illuminated sensor, as known in the art. For example, such pixels may be fabricated with the typical back-side processes applied to the first wafer, for example, thinning, addition of layers to include the color filter array, micro-lens, anti-reflection coating, opaque layer to define dark reference pixels, and backside passivation layers.

One of skill in the art may readily configure control signals and their timing schemes for effective operation of the stacked pixels.

In a standard pixel, due to crowding of components, isolation structures (for example, structures made by STI and LOCOS processes) are required to prevent spillover, leakage, and crosstalk. In the simplified design of the invention, the photodiode is spatially separated from the other components and in many embodiments, the design of the invention minimizes or eliminates the need for fabrication of such isolation structures. Accordingly, fabrication schemes are simplified and quality/performance is enhanced due to the reduced or obviated need for isolation structures in the top, bottom, or both wafers.

The stacked pixel designs of the invention afford great flexibility in the selection of materials. Accordingly, for the first, second, or both wafers, a substrate material may be selected that enhances isolation of pixels from adjacent pixels or which enhances isolation of components in the same pixel from each other. For example, in the first wafer, lightly doped materials, such as are used in deeply depleted image sensors, may be used to obviate or eliminate the need for isolation structures.

In one embodiment, the invention comprises a stacked pixel, wherein isolation structures are not present in the first wafer, the second wafer, or both wafers.

The pixels of the invention may further comprise pixel optical components, for example microlens assemblies, color filter assemblies, anti-reflective coatings, and other pixel optical components known in the art. The invention further encompasses image sensors comprising arrays of the stacked pixels described herein.

### Methods of Fabrication and Devices Made Therefrom.

In another aspect, the invention comprises novel methods of fabrication, and devices made using such methods. In the elemental wafers of the invention, fabrication of structures other than the photodiode, transfer gate, and interconnects are omitted.

One advantage of an elemental wafer, is that the fabrication thermal budget is less constrained than that of a “standard wafer,” herein defined as a wafer comprising a photodiode and all other components required for pixel function. On the crowded standard wafer, thermal budgets must be constrained to avoid heat-induced defects from migrating dopants and other artifacts of processing. In the elemental wafers of the invention, processing artifacts for other components are not an issue, and are less constrained. In one embodiment, the invention comprises an elemental wafer comprising one or more pixels, each such pixel comprising a pinned photodiode, a transfer gate, and two interconnects, and wherein the processing regime utilized to create such wafer has a thermal budget of greater than 150%, 200%, 300% or 500% of the thermal budget utilized to create a standard wafer, wherein the pixels of the standard wafer have comparable photodiode size (for example, measured as well capacity, area, or other measure of photodiode size).

In another embodiment, the invention comprises a method of fabricating an elemental wafer, wherein the processing regime utilized to create such wafer has a thermal budget of greater than 150%, 200%, 300% or 500% of the thermal budget utilized to create a standard wafer, wherein the pixels of the standard wafer have comparable photodiode size.

Another advantage of the elemental wafers of the invention is the greatly simplified processing that can be utilized to fabricate such wafers. For example, fabrication of a standard wafer requires at least thirty to fifty masks, or more. The elemental wafers of the invention may be fabricated by minimal processing regimens, for example, being fabricated in a process regimen using fifteen, fourteen, thirteen, twelve, eleven, ten, nine, eight, or seven masks. For example, in one embodiment, the invention comprises an elemental wafer comprising one or more pixels, each such pixel comprising a pinned photodiode, a transfer gate, and two interconnects, and wherein the processing regime utilized to create such elemental wafer utilizes fifteen, fourteen, thirteen, twelve, eleven, ten, nine, eight, seven, or less than seven masks.

In another embodiment, the invention comprises a method of fabricating an elemental wafer, wherein the processing regime utilized to create such wafer utilizes fifteen, fourteen, thirteen, twelve, eleven, ten, nine, eight, seven, or less than seven masks.

In another aspect, the invention comprises a stacked pixel comprising a first elemental wafer, wherein the fabrication of the first wafer utilizes a minimized process regime, relative to a standard wafer. For example, various process steps which are inherent in the fabrication of a standard wafer may be omitted in the fabrication of an elemental wafer. For example, a standard wafer is typically fabricated utilizing the following process steps (“standard wafer process steps”), as known in the art: Via2, Metal2, Via3, Metal3, Via3, Metal4, Deep Nwell, Nwell, Pwell, Array salicide block, NMOS transistor source/drain, PMOS transistor source/drain, Shallow trench isolation, N-lightly doped drain implant, P-lightly doped drain implant, and ESD. In one embodiment, the invention comprises an elemental wafer which is fabricated without utilizing any of the standard wafer process steps. In another embodiment, the invention comprises an elemental wafer which is fabricated using less than five standard wafer process steps. In another embodiment the invention comprises an elemental wafer which is fabricated using less than three standard wafer processing steps. In another embodiment, the invention comprises a method of fabricating an elemental sensor utilizing no standard wafer processing steps. In another embodiment, the invention comprises a method of fabricating an elemental sensor utilizing less than five standard wafer processing steps. In another embodiment, the invention comprises a method of fabricating an elemental sensor utilizing less than three standard wafer processing steps.

All patents, patent applications, and publications cited in this specification are herein incorporated by reference to the same extent as if each independent patent application, or publication was specifically and individually indicated to be incorporated by reference. The disclosed embodiments are presented for purposes of illustration and not limitation. While the invention has been described with reference to the described embodiments thereof, it will be appreciated by those of skill in the art that modifications can be made to the structure and elements of the invention without departing from the spirit and scope of the invention as a whole.

1. An stacked pixel comprising
a first wafer, comprising a photodiode, a transfer gate, and two interconnects; and
a second wafer, comprising a reset transistor, a source-follower amplifier, a row select transistor, and a column bus connection; wherein
the two wafers are bonded together and are connected by one or more interconnects sufficient for ensuring the coordinated operation of the elements as a functional pixel.

2. The stacked pixel of claim 1, wherein
the floating diffusion node of the pixel comprises the doped region on the drain side of the transfer gate on the first wafer;
a metal stack structure on the second wafer; and
an interconnect which connects the doped region on the first wafer with the metal stack on the second wafer.

3. The stacked pixel of claim 2, wherein
the metal stack comprises a multi-layer_{[BM1]} metal stack.

4. The stacked pixel of claim 3, wherein
the metal stack has a parasitic capacitance of less than 0.1 fempto-Farad.

5. The stacked pixel of claim 1, wherein
the first wafer comprises a low-doped silicon wafer.

6. The stacked pixel of claim 1, wherein
the photodiode on the first wafer comprises a material selected from the group consisting of: intrinsic silicon, p-doped silicon, n-doped silicon, gallium arsenide, indium gallium arsenide, and germanium.

7. The stacked pixel of claim 1, wherein
no isolation structures are present on the first wafer.

8. The stacked pixel of claim 1, wherein
no isolation structures are present on the second wafer.

9. The stacked pixel of claim 1, wherein
no isolation structures are present on the first or second wafer.

10. An elemental wafer, comprising
an array of pinned photodiodes, each photodiode having an adjacent transfer gate, a first interconnect connected to the transfer gate's gate terminal, and second interconnect connected to the doped region on the drain side of the transfer gate.

11. The elemental wafer of claim 10, wherein
the elemental wafer is aligned with and bonded to a second wafer comprising an array of pixel components, such that each photodiode and transfer gate of the first wafer is connected to pixel components on the second wafer which enable readout and reset of the each photodiode; and
such that the stacked wafers comprise a functional image sensor comprising an array of stacked pixels.

12. The elemental wafer of claim 11, wherein
the array of stacked pixels comprises a backside-illuminated image sensor.

13. The elemental wafer of claim 11, wherein
each stacked pixel comprises a micro-lens and the array of stacked pixels comprises an overlaying color filter array.

14. The elemental wafer of claim 10, wherein
the processing regime utilized to create the elemental wafer utilizes fifteen or less masks.

15. The elemental wafer of claim 10, wherein
the processing regime utilized to create the elemental wafer utilizes twelve or less masks.

16. The elemental wafer of claim 10, wherein
the processing regime utilized to create the elemental wafer utilizes twelve or less masks.

17. The elemental wafer of claim 10, wherein
the processing regime utilized to create the elemental wafer comprises a thermal budget of greater than 150% of the thermal budget utilized to create a standard wafer comprising photodiodes of comparable size to the photodiodes present on the elemental wafer.

18. The elemental wafer of claim 10, wherein
the processing regime utilized to create the elemental wafer does not comprise any of the following processing steps: Via2, Metal2, Via3, Metal3, Via3, Metal4, Deep Nwell, Nwell, Pwell, Array salicide block, NMOS transistor source/drain, PMOS transistor source/drain, Shallow trench isolation, N-lightly doped drain implant, P-lightly doped drain implant, and ESD.
